(19) United States
(12) Patent Application Publication
(10) Pub. No.: US 2014/0367640 A1
(43) Pub. Date: Dec. 18, 2014

(54) LIGHT-EMITTING ELEMENT, EPITAXIAL WAFER, AND METHOD FOR PRODUCING THE EPITAXIAL WAFER

(71) Applicant: Sumitomo Electric Industries, Ltd., Osaka-shi (JP)

(72) Inventors: Kei Fujii, Itami-shi (JP); Takashi Ishizuka, Itami-shi (JP); Katsushi Akita, Itami-shi (JP)

(21) Appl. No.: 14/376,388

(22) PCT Filed: Jan. 30, 2013
(86) PCT No.: PCT/JP2013/051995

§ 371 Date: Aug. 1, 2014

(30) Foreign Application Priority Data
Feb. 20, 2012 (JP) 2012-034400

(51) Int. Cl. H01L 33/06; H01L 33/30; H01L 33/00

(52) U.S. Cl. CPC H01L 33/06; H01L 33/0062; H01L 33/30
USPC 257/13; 438/47

(57) ABSTRACT

Provided are an epitaxial wafer and a light-emitting element having a type-II MQW formed of III-V compound semiconductors and configured to emit light with a sufficiently high intensity. The method includes a step of growing an active layer having a type-II multi-quantum well structure (MQW) on a III-V compound semiconductor substrate, wherein, in the step of forming the type-II multi-quantum well structure, the type-II multi-quantum well structure is formed by metal-organic vapor phase epitaxy using only metal-organic sources such that a number of pairs of the type-II multi-quantum well structure is 25 or more.

### TECHNICAL FIELD

The present invention relates to a light-emitting element, an epitaxial wafer, and a method for producing the epitaxial wafer. Specifically, the present invention relates to a light-emitting element formed of III-V compound semiconductors and configured to emit light in the near infrared region; an epitaxial wafer; and a method for producing the epitaxial wafer.

### BACKGROUND ART

Type-II multi-quantum well structures (MQWs) formed of III-V compound semiconductors have a cutoff wavelength corresponding to the near infrared region and hence a large number of studies are performed for developing photodiodes for observation of tissues of animals and plants, communications, image capturing at night, and the like.

Regarding light-emitting elements, type-I MQWs have been mainly used. However, light-emitting elements for the above-described near infrared region preferably have type-II MQWs.

In the case of light emission from a type-I MQW, which has a high transition probability, even when the film thickness or the number of pairs of the light-emitting layer is small, a sufficiently high emission intensity can be achieved. However, in the case of light emission from a type-II MQW, which has a low transition probability, the number of pairs needs to be increased in order to achieve a sufficiently high emission intensity. However, as the number of pairs is increased, defects are accumulated in the quantum wells, so that it becomes difficult to achieve high crystallinity.

Non Patent Literature 1 discloses, in example cases of a light-emitting diode (LED) and a laser diode (LD) formed of InP-based compound semiconductors, an example of an active layer constituted by a type-II MQW in which the number of (InGaAs/GaAsSb) pairs is limited to the range of 10 to 20 for the above-described reason. In this example, the epitaxial layer structure is grown on an InP substrate by metal-organic vapor phase epitaxy (MOVPE).

### CITATION LIST

### Non Patent Literature

NPL 1: M. Peter, et. al. “Light-emitting diodes and laser diodes based on a Ga₁₋ₓInₓAs/GaAs_{1-y}Sb_{y} type II superlattice on InP substrate”, Appl. Phys. Lett., Vol. 74, No. 14, April 1999

### SUMMARY OF INVENTION

### Technical Problem

However, such LEDs and the like each having a type-II MQW constituted by 10 to 20 pairs of (InGaAs/GaAsSb) do not achieve a sufficiently high emission intensity. The transition probability of light emission in a type-II MQW is low and the emission intensity is low, compared with light-emitting elements including a bulk crystal or a type-I MQW having a film thickness similar to that of the type-II MQW. In order to enhance the emission intensity, the number of pairs needs to be increased. However, when the number of pairs is increased, defects are generated at interfaces between quantum wells. As the number of pairs is increased, the defects are accumulated and inherited by upper layers. As a result, the crystallinity is degraded and the emission intensity is decreased. In addition, as defects increase, the carrier diffusion length becomes shorter. For this reason, even when the number of pairs is increased, many of the pairs cannot contribute to light emission. This results in a decrease in the emission intensity.

For this reason, currently, there is no light-emitting element having a type-II MQW active layer configured to emit light in the near infrared region with a sufficiently high intensity.

An object of the present invention is to provide a light-emitting element having a type-II MQW formed of III-V compound semiconductors and configured to emit light with a sufficiently high intensity; an epitaxial wafer serving as an intermediate material for the light-emitting element; and a method for producing the epitaxial wafer.

### Solution to Problem

A method for producing an epitaxial wafer according to the present invention is a method for producing an epitaxial wafer including an epitaxial layer structure formed of III-V compound semiconductors. This method includes a step of growing an active layer having a type-II multi-quantum well structure (MQW) on a III-V compound semiconductor substrate, wherein, in the step of forming the type-II multi-quantum well structure, the type-II multi-quantum well structure is formed by metal-organic vapor phase epitaxy using only metal-organic sources such that a number of pairs of the type-II multi-quantum well structure is 25 or more.

Here, the metal-organic vapor phase epitaxy using only metal-organic sources, which is referred to as all metal-organic source MOVPE, denotes epitaxy in which only metal-organic sources constituted by compounds between organic substances and metals are used as the sources for vapor phase epitaxy.

According to the above-described production method, all the epitaxial layers are deposited by all metal-organic source MOVPE. In all metal-organic source MOVPE, decomposition efficiency of source gases is high and intermediate reaction products are not likely to be generated. Thus, source gases that hamper formation of sharp composition change are not likely to remain in near-substrate regions relating to crystal growth. Accordingly, even when the number of pairs of a MQW is increased, epitaxial layers having high crystallinity can be obtained. Even when the number of pairs of a MQW is increased to 25 or more, the carrier diffusion length becomes sufficiently large and the whole MQW contributes to light emission, resulting in an increase in the emission intensity. The number of pairs of the existing light-emitting elements is 20 or less; however, as described above, it can be increased to 25 or more, or 50 or more. The number of pairs may be 100 or more. However, an excessively large number of pairs causes degradation of crystallinity even with all metal-organic source MOVPE. Accordingly, the upper limit of the number of pairs is preferably about 300.

The light-emitting element is not limited as long as it is an element configured to emit light. The light-emitting element may be any light-emitting element such as an LED (light emitting diode) or an LD (laser diode).

By growing the type-II multi-quantum well structure at a growth temperature of 500° C. or less, projections or depressions can be formed at a number density of 100/cm² or more in a surface of the epitaxial layer structure.

By forming a surface pattern constituted by projections or depressions in the surface, light emitted from the active layer is not likely to undergo total reflection at the surface of the contact layer, so that emission of the light from the surface of the epitaxial layer structure or the contact layer is facilitated. Stated another way, light extraction is enhanced so that emission intensity can be increased. In general, generation of defects also causes surface roughening or formation of irregularities; however, generation of defects causes a decrease in the emission intensity. According to studies performed by the inventors, the special surface pattern does not result from defects and does not cause a decrease in the emission intensity. In the growth performed by standard MOVPE, the decomposition efficiency of sources is low and hence deposition at 500° C. or less is difficult to achieve. However, all metal-organic source MOVPE allows high decomposition efficiency of sources even at 500° C. or less, so that a multi-quantum well structure having high crystallinity can be formed. Note that, in the growth temperature range of 500° C. or less, as the number of pairs is increased, the surface pattern is formed in the surface of the contact layer. The reason for this is not known; however, this occurs with 100% reproducibility.

The above-described projections or depressions each have a diameter of about 30 μm or less. When the number of projections or depressions per unit area exceeds 10⁶/cm², the whole surface is crowded with and covered with the projections or depressions and counting of individual projections or depressions becomes difficult to perform. When the number density is 10⁶/cm² or less, counting can be achieved with effort. The planar shape of projections or depressions is often a circle, but, in some cases, an elongated rectangle or an ellipse. In such cases, “the diameter measured in the shorter length direction” is defined as the diameter. The lower limit of the diameter is about 5 μm or more.

The growth temperature denotes substrate surface temperature obtained by monitoring with a pyrometer including an infrared camera and an infrared spectrometer. This temperature is called substrate surface temperature, but it is strictly the temperature of the surface of an epitaxial layer being deposited on the substrate. The temperature is referred to as various names such as substrate temperature, growth temperature, and deposition temperature; however, these names denote the above-described temperature obtained by monitoring.

The type-II multi-quantum well structure is preferably grown at a growth temperature of 450° C. or more.

When the growth temperature is set to less than 450° C., the lattice defect density is increased because of the low-temperature growth, resulting in degradation of crystallinity and a decrease in emission intensity. For this reason, the growth temperature is preferably set to 450° C. or more.

A step of forming a contact layer formed of a III-V compound semiconductor may be further included, the step being performed after the step of forming the type-II multi-quantum well structure, wherein the metal-organic vapor phase epitaxy using only metal-organic sources is performed within the same growth chamber from initiation of growth of the multi-quantum well structure to end of growth of the contact layer, so that a step of forming a regrown interface does not occur between the step of forming the multi-quantum well structure and the step of forming the contact layer.

In this case, the epitaxial layer structure may include a phosphorus- (P-) containing layer.

As a result, the following advantages can be provided.

(E1) Deposition of a phosphorus-containing layer such as InP is difficult to perform by a deposition method other than all metal-organic source MOVPE, such as molecular beam epitaxy (MBE). The reason for this is as follows. In MBE, the sources used are solid sources. Accordingly, the source of phosphorus (P) for an InP window layer is solid phosphorus. Thus, as the deposition proceeds, solid phosphorus that is a residue from the deposition accumulates on the walls of the deposition chamber. The solid phosphorus source has high ignitability. Hence, there is a high probability of the occurrence of fire accidents when the apparatus is in an open state, such as during charging sources or during maintenance in MBE. A preventive measure against fire accidents needs to be taken. In contrast, all metal-organic source MOVPE (also standard MOVPE) does not use any solid material as the P source and hence is excellent in terms of safety and the like. In addition, MOVPE is advantageous in terms of growth efficiency, compared with MBE.
(E2) In addition, all metal-organic source MOVPE uses, as source gases for phosphorus-containing layers such as InP, only metal-organic source gases such as tertiarybutylphosphine (TBP) and trimethylindium (TMI). Thermal decomposition of such metal-organic source gases is easily achieved and the growth temperature can be set to 500° C. or less. Thus, by growing a phosphorus-containing layer such as an InP cladding layer by all metal-organic source MOVPE, for example, thermal decomposition of the underlying multi-quantum well structure can be suppressed.

When a phosphorus-containing layer such as an InP cladding layer is grown without using any metal-organic source gas, a method using PH₃ (phosphine) as a phosphorus source may be used. However, PH₃ has a high thermal decomposition temperature and growth of InP at 500° C. or less is difficult to perform.

(E3) Since exposure to the air is not caused, regrown interfaces containing oxygen or carbon are not included. As a result, high crystallinity can be ensured.

Here, such a regrown interface is defined as follows. A first crystalline layer is grown by a predetermined growth method and then temporarily exposed to the air, and a second crystalline layer is grown on and in contact with the first crystalline layer by another growth method. The regrown interface denotes the interface between the first crystalline layer and the second crystalline layer. Such regrown interfaces satisfy at least one of an oxygen concentration of 1×10¹⁷ cm⁻³ or more and a carbon concentration of 1×10¹⁷ cm⁻³ or more.

(E4) Since the process is continuously performed in the same single growth chamber, the epitaxial wafer can be efficiently obtained in a short time.

The III-V compound semiconductor substrate may be an InP substrate and the type-II multi-quantum well structure may have pairs of (InGaAs/GaAsSb).

This allows emission of light having a wavelength in the near infrared region. In such a multi-quantum well, (InGaAs/GaAsSb) each preferably have a layer thickness in the range of 2 nm or more and 6 nm or less, and preferably have a pair thickness in the range of 4 nm or more and 12 nm or less.

An epitaxial wafer according to the present invention is an epitaxial wafer for a light-emitting element, the epitaxial wafer including an epitaxial layer structure formed of III-V compound semiconductors. This epitaxial wafer includes a III-V compound semiconductor substrate, and a type-II multi-quantum well structure disposed on the substrate, wherein a number of pairs of the type-II multi-quantum well structure is 25 or more.

As a result, a light-emitting element having a high emission intensity can be obtained. As described above, the number of pairs of the existing light-emitting elements is 20 or less; however, it is preferably increased to 25 or more, or 50 or more. The number of pairs may be 100 or more. However, an excessively large number of pairs causes degradation of crystallinity. Accordingly, the number of pairs is preferably about 300 or less.

A contact layer may be further included in a surface of the epitaxial layer structure. In addition, the contact layer may be formed of InGaAs. By forming the contact layer with InGaAs, compared with the case where electrodes are directly formed on InP, the contact resistance can be decreased.

The surface of the epitaxial layer structure may have projections or depressions at a number density of 100/cm² or more.

By forming a surface pattern constituted by projections or depressions in the surface, light emitted from the active layer is not likely to undergo total reflection at the surface of the epitaxial layer structure or the contact layer, so that emission of the light through the surface of the epitaxial layer structure to the outside is facilitated. For this purpose, projections or depressions having a number density of 10²/cm² or more are necessary. As described above, as the number of pairs is increased, the density of the projections or depressions is increased. When the number density exceeds 10⁶/cm², the whole surface is crowded with and covered with the projections or depressions and counting of individual projections or depressions becomes difficult to perform. However, even in this state, the effect of facilitating emission of light from the active layer, through the surface of the contact layer, to the outside is provided. Note that, the number density is desirably 10⁶/cm² or less because an increase in the number of pairs causes degradation of crystallinity and sufficient light emission cannot be obtained.

Regarding the projections or depressions, as the number of pairs is increased and as the growth temperature is decreased in the growth temperature range of 500° C. or less, the surface pattern is formed in the surface of the epitaxial layer structure.

The projections or depressions are measured in the above-described manner.

The type-II multi-quantum well structure may be a multi-quantum well structure having pairs of (InGaAs/GaAsSb).

In this case, a light-emitting element configured to emit light having a wavelength in the near infrared region can be obtained; in addition, the peak wavelength of photo luminescence (PL) can be made to be 2000 nm or more and 3000 nm or less. In such a multi-quantum well structure, (InGaAs/GaAsSb) each preferably have a layer thickness in the range of 2 nm or more and 6 nm or less, and preferably have a pair thickness in the range of 4 nm or more and 12 nm or less.

A substrate-side first-conductivity-type InP cladding layer disposed on a substrate side and a surface-side second-conductivity-type InP cladding layer disposed on a surface side may be included such that the cladding layers sandwich the type-II multi-quantum well structure therebetween.

In this case, cladding layers formed of InP having a wide bandgap sandwich the active layer, so that leakage of carriers is suppressed and light emission of an LED (light emitting diode) or the like can be promoted. Other than InP cladding layers, there are InGaAs layers and InGaAsP layers. However, these layers have a smaller bandgap than InP and InP cladding layers are better in terms of suppression of leakage of carriers. InGaAs layers, InGaAsP layers, and the like, which have a high refractive index, are suitable as light guide layers or the like in LDs (laser diodes) and are disclosed in a large number of examples. However, for LEDs, such layers are not particularly necessary and InP cladding layers are preferably used in terms of quality of heterointerfaces and in view of non-necessity of quaternary system growth requiring crystal growth techniques. It is also unusual that InP cladding layers are used as cladding layers disposed on both sides of the active layer.

A configuration may be employed in which no regrown interface is present between the type-II multi-quantum well structure and a surface of the epitaxial layer structure.

In this case, since no regrown interface is present, an epitaxial layer structure having a low lattice defect density and high crystallinity can be obtained.

A light-emitting element according to the present invention is produced from any one of the above-described epitaxial wafers.

In this case, a light-emitting element having a high emission intensity can be obtained.

### Advantageous Effects of Invention

For example, from an epitaxial wafer according to the present invention, a light-emitting element can be obtained that has a type-II MQW formed of III-V compound semiconductors and is configured to emit light with a sufficiently high intensity.

### BRIEF DESCRIPTION OF DRAWINGS

FIG. 1 illustrates an epitaxial wafer according to an embodiment of the present invention.

FIG. 2 is a flow chart for producing the epitaxial wafer in FIG. 1.

FIG. 3 illustrates the piping system and the like of a deposition apparatus for all metal-organic source MOVPE.

FIG. 4A illustrates flow of metal-organic molecules and thermal flow.

FIG. 4B is a schematic view of metal-organic molecules on a substrate surface.

FIG. 5A is a schematic view of the surface of a contact layer in Invention example A1 in Example 1.

FIG. 5B is a schematic view of the surface of a contact layer in Invention example A2 in Example 1.

FIG. 5C is a schematic view of the surface of a contact layer in Invention example A3 in Example 1.

FIG. 6A is a schematic view of the surface of a contact layer in Comparative example B1 in Example 1.

FIG. 6B is a schematic view of the surface of a contact layer in Invention example A4 in Example 1.

FIG. 7A is a graph illustrating a relationship between PL intensity and wavelength in Invention example A1 in Example 1.

FIG. 7B is a graph illustrating a relationship between PL intensity and wavelength in Invention example A2 in Example 1.

FIG. 7C is a graph illustrating a relationship between PL intensity and wavelength in Invention example A3 in Example 1.

FIG. 8A is a graph illustrating a relationship between PL intensity and wavelength in Comparative example B1 in Example 1.

FIG. 8B is a graph illustrating a relationship between PL intensity and wavelength in Invention example A4 in Example 1.

FIG. 9A is a schematic view of the surface of a contact layer in Invention example A5 in Example 2.

FIG. 9B is a schematic view of the surface of a contact layer in Invention example A3 in Example 2.

FIG. 9C is a schematic view of the surface of a contact layer in Invention example A6 in Example 2.

FIG. 10A is a graph illustrating a relationship between PL intensity and wavelength in Invention example A5 in Example 2.

FIG. 10B is a graph illustrating a relationship between PL intensity and wavelength in Invention example A3 in Example 2.

FIG. 10C is a graph illustrating a relationship between PL intensity and wavelength in Invention example A6 in Example 2.

### REFERENCE SIGNS LIST

1 InP substrate; 2 substrate-side n-type cladding layer; 3 type-II MQW (active layer); 4 surface-side p-type cladding layer; 5 p-type contact layer; 10 epitaxial wafer (light-emitting element); 10a epitaxial wafer during growth; 60 deposition apparatus for all metal-organic source MOVPE; 61 infrared thermometer; growth chamber; 65 quartz tube; 66 substrate table; 66h heater; 69 window of growth chamber.

### DESCRIPTION OF EMBODIMENTS

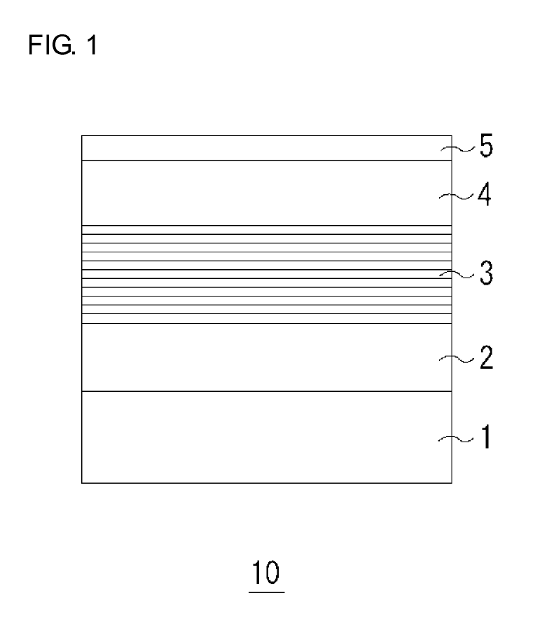

FIG. 1 is a sectional view illustrating an epitaxial wafer 10 for forming a light-emitting element according to an embodiment of the present invention. In FIG. 1, the epitaxial wafer 10 includes, on an InP substrate 1, an epitaxial layer structure formed of III-V compound semiconductors and having the following configuration. (InP substrate 1/substrate-side n-type cladding layer 2/active layer 3 constituted by (InGaAs/GaAsSb) type-II MQW/surface-side p-type cladding layer 4/p-type contact layer 5)

In the type-II MQW constituted by pairs of (InGaAs/GaAsSb), the combination of the film thicknesses is not particularly limited, but the thickness of each layer can be appropriately selected from the range of 2 nm to 6 nm.

For example, (4 nm/4 nm) is preferably selected. The number of pairs is not particularly limited as long as it is 25 or more. For example, the number of pairs is preferably 50 or more and about 300 or less.

The cladding layers 2 and 4 may be formed of any III-V compound semiconductor that has a bandgap larger than the bandgap of the active layer 3 and, for example, may be formed of InP. That is, the substrate-side n-type InP cladding layer 2 and the surface-side p-type InP cladding layer 4 can be disposed so as to sandwich the active layer 3. In this case, the substrate-side n-type InP cladding layer 2 is preferably formed so as to have a thickness of 1000 nm (1 μm) and doped with Si so as to have a carrier concentration of 1×10¹⁸ cm⁻³. The surface-side p-type InP cladding layer 4 is preferably formed so as to have a thickness of 800 nm and doped with Zn so as to have a carrier concentration of 1×10¹⁸ cm⁻³. The cladding layers 2 and 4 may be formed of InP, InGaAs, or InGaAsP. However, InP has a wider bandgap and hence is suitable for carrier confinement. For example, this is preferable for LED applications.

The p-type contact layer 5 may be formed of any III-V compound semiconductor that can easily form an ohmic contact with a p-electrode (not shown) and has such a large bandgap that does not cause absorption of light emission from the active layer 3. For example, the p-type contact layer 5 may be formed of InGaAs. The p-type InGaAs layer 5 is preferably formed so as to have a thickness of, for example, about 200 nm and doped with Zn so as to have a carrier concentration of 1×10¹⁹ cm⁻³. In order to produce a light-emitting element, an n-electrode (not shown) used in pair with the p-electrode is disposed on the substrate-side n-type InP cladding layer 2; and carriers are injected between the n-electrode and the p-electrode, so that type-II transition is caused in the active layer 3.

During emission of light, electron transition (type-II transition) occurs from the conduction band of InGaAs, which is a layer having the conduction band at a lower energy, to the valence band of GaAsSb, which is a layer having the valence band at a higher energy. The wavelength corresponding to the energy difference of the transition falls within the near infrared region. The probability of the occurrence of type-II transition is in proportion to the product of the wave function of an electron in the conduction band of InGaAs and the wave function of an electron in the valence band of GaAsSb. However, the wave functions spatially deviate from each other and the overlap therebetween is small, so that the product becomes small. Thus, addition of such product values of about 10 pairs does not provide a large value. However, according to the present invention, by increasing the number of pairs, an emission intensity of sufficient level can be achieved. Here, the challenge is that, while the number of pairs is increased, a crystalline layer having a low lattice defect density is obtained. This will be described below. One of important points of the present invention is that the type-II MQW constituting the active layer 3 is formed so as to have 25 or more pairs. The number of pairs may be 50 or more, or 100 or more.

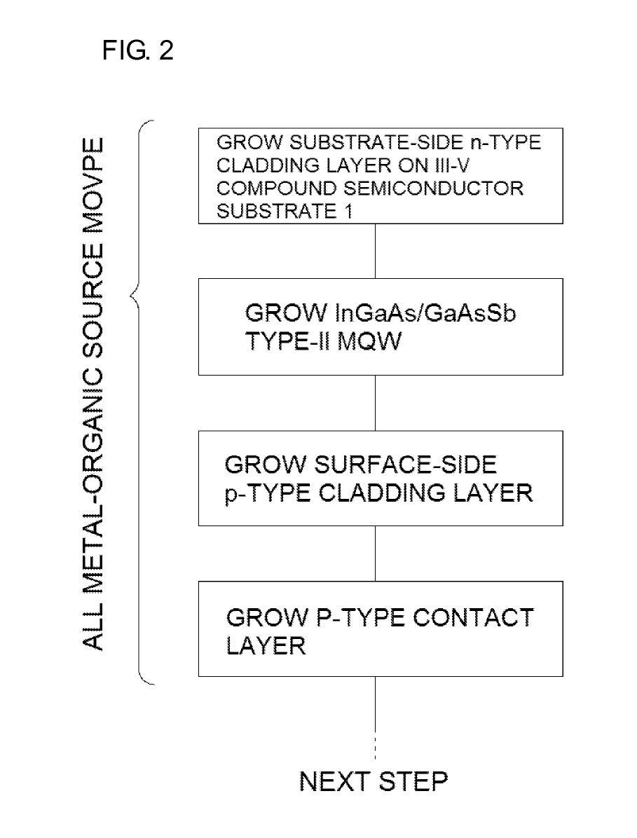

FIG. 2 is a flow chart illustrating the growth process of an epitaxial layer structure. A III-V compound semiconductor substrate, for example, an InP substrate is set on a substrate table of a growth chamber in which all metal-organic source MOVPE is to be performed. On this InP substrate, a substrate-side n-type InP cladding layer is grown so as to have a thickness of 1000 nm. This InP cladding layer also has the role of a buffer layer. This layer is doped with Si serving as a dopant so as to have a carrier concentration of 1×10¹⁸ cm⁻³. Subsequently, an active layer constituted by a type-II MQW (InGaAs/GaAsSb) is grown at a growth temperature of 500° C. or less so as to have 25 or more (4 nm/4 nm) pairs, for example, 50 pairs to 250 pairs. The growth temperature may be set to 500° C. or less in advance during the growth of the substrate-side n-type cladding layer 2. Subsequently, the surface-side p-type InP cladding layer 4 is grown so as to have a thickness of 800 nm. This layer is doped with Zn serving as a dopant so as to achieve 1×10¹⁸ cm⁻³. Subsequently, the p-type InGaAs contact layer 5 is grown on the surface side so as to have a thickness of 200 nm. This layer is doped with Zn serving as a dopant so as to achieve 1×10¹⁹ cm⁻³.

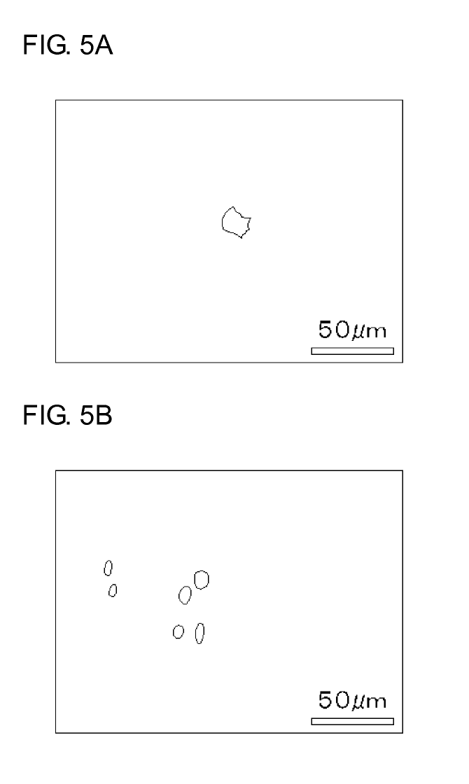

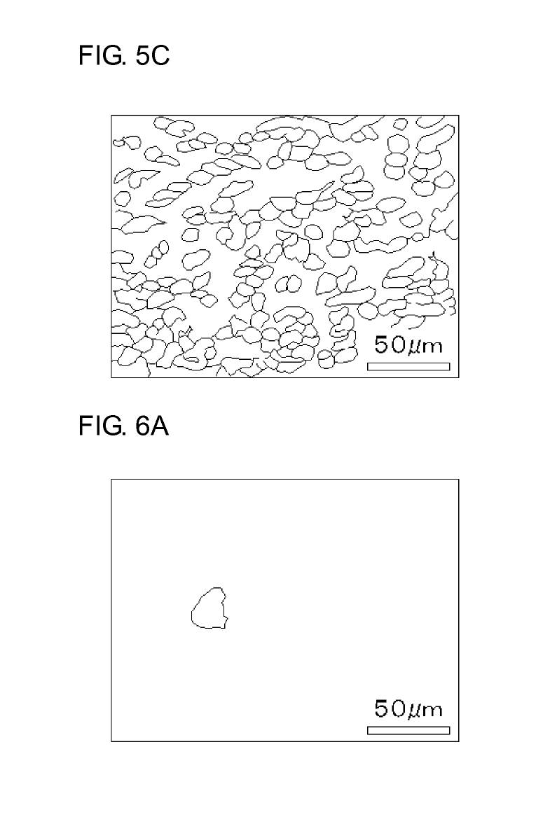

The growth temperature of the type-II MQW (InGaAs/GaAsSb) is set to 500° C. or less in order to form projections or depressions having a diameter of 30 μm or less in the surface of the contact layer 5, which constitutes the surface layer of the epitaxial layer structure (refer to FIGS. 5A, 5B, 5C, 6A, 6B, 9A, 9B, and 9C). The mechanism of the formation of such projections or depressions is not known. In addition, as long as the number of pairs is not excessively large and such projections or depressions are formed, the type-II MQW or the like has high crystallinity, the reason for which is also not known. The phenomenal findings of projections or depressions in the surface of the contact layer are summarized below.

1. The projections or depressions are generated by setting the growth temperature of the type-II MQW 3 to about 500° C. or less. At a growth temperature of 525° C., the projections or depressions are not substantially generated (in the case of 250 pairs). As the growth temperature is decreased from about 500° C., the density of the projections or depressions (number thereof per unit area) is decreased. These findings are based on the case where the number of pairs of the type-II MQW is 250.
2. While the growth temperature is fixed at 500° C., the number of pairs of the type-II MQW is changed. As the number of pairs is increased, the density of the projections or depressions is increased. When the number of pairs of the type-II MQW is about 250, the number density becomes 10⁶ cm⁻². In this case, the emission intensity is maximized.
3. When the number of pairs of the type-II MQW 3 is excessively large, the projections or depressions are generated beyond the number density of 10⁶ cm⁻² and cover the whole surface. In this case, the crystallinity of the type-II MQW 3 or the like is also degraded due to the excessively large number of pairs. An increase in the number of pairs of the type-II MQW 3 is a factor causing degradation of crystallinity. Accordingly, the direct cause of a decrease in the light-emitting efficiency in the case of, for example, 300 or more pairs is not the influence of the projections or depressions but degradation of the crystallinity of MQW itself.
4. In view of all the above-described phenomena and the like, the reason why projections or depressions generated in the surface of the contact layer 5 enhance the emission intensity is as follows. When light is generated in the type-II MQW and the light is emitted through the surface of the contact layer 5, such projections or depressions suppress the occurrence of total reflection, so that the transmittance (emission ratio) of the light to the outside is enhanced.

Even when the number of pairs of the type-II MQW 3 is increased to 25 or more, for example, 50 or more, high crystallinity can be ensured. This is achieved by the growth method.

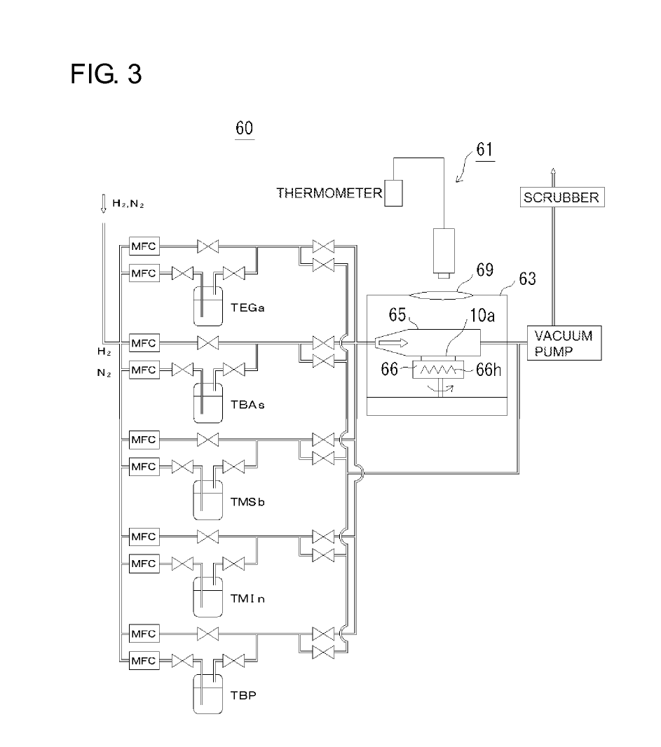

FIG. 3 illustrates the piping system and the like of a deposition apparatus 60 for all metal-organic source MOVPE. A quartz tube 65 is disposed in a growth chamber (chamber) 63. Source gases are introduced into the quartz tube 65. In the quartz tube 65, a substrate table 66 is rotatably and hermetically disposed. The substrate table 66 is equipped with a heater 66h for heating a substrate. The surface temperature of an epitaxial wafer 10a during deposition is monitored with an infrared thermometer 61 through a window 69 disposed in the ceiling portion of the growth chamber 63. This monitored temperature is referred to as, for example, the temperature during growth, the growth temperature, or the substrate temperature. Regarding formation of a MQW at a growth temperature of 500° C. or less in a production method according to the present invention, this temperature of 500° C. or less is a temperature measured in the temperature monitoring. Forced evacuation of the quartz tube 65 is performed with a vacuum pump.

Source gases are supplied through pipes that are connected to the quartz tube 65. All metal-organic source MOVPE has a feature of supplying all the source gases in the form of metal-organic sources that are constituted by compounds between organic substances and metals. Although FIG. 3 does not describe source gases of, for example, impurities that govern the conductivity type, impurities are also introduced in the form of metal-organic sources. The metal-organic sources are contained in constant temperature baths and kept at constant temperatures. The carrier gases used are hydrogen (H₂) and nitrogen (N₂). The metal-organic sources are carried with the carrier gases and sucked with the vacuum pump to thereby be introduced into the quartz tube 65. The flow rates of the carrier gases are accurately controlled with mass flow controllers (MFCs). A large number of mass flow controllers, electromagnetic valves, and the like are automatically controlled with microcomputers.

After the substrate-side cladding layer 2 is grown, the active layer 3 having a type-II MQW is formed in which the quantum well is constituted by the pairs of InGaAs/GaAsSb. In the MQW, GaAsSb has a film thickness of, for example, 4 nm; and InGaAs has a film thickness of, for example, 4 nm. In the growth of GaAsSb, triethylgallium (TEGa), tertiarybutylarsine (TBAs), and trimethylantimony (TMSb) are used. As for InGaAs, TEGa, trimethylindium (TMIn), and TBAs can be used. These source gases are all metal-organic sources. Accordingly, the gases can be completely decomposed at a temperature of 450° C. or more and 500° C. or less to contribute to crystal growth. The active layer 3 having a type-II MQW can be formed by all metal-organic source MOVPE so as to have sharp composition changes at interfaces in the quantum well. As a result, spectrophotometry can be performed with high accuracy.

The Ga (gallium) source may be TEGa (triethylgallium) or trimethylgallium (TMGa). The In (indium) source may be TMIn (trimethylindium) or triethylindium (TEIn). The As (arsenic) source may be TBAs (tertiarybutylarsine) or trimethylarsenic (TMAs).

The Sb (antimony) source may be TMSb (trimethylantimony), triethylantimony (TESb), triisopropylantimony (TIPSb), or trisdimethylaminoantimony (TDMASb).

The metal-organic sources are carried through pipes, introduced into the quartz tube 65, and discharged. Any number of metal-organic sources may be supplied to the quartz tube 65 by increasing the number of pipes. For example, even more than ten source gases can be controlled by opening/closing of electromagnetic valves.

The flow rates of the metal-organic sources are controlled with mass flow controllers (MFCs) illustrated in FIG. 3 and introduction of the metal-organic sources into the quartz tube 65 is turned on/off by opening/closing of electromagnetic valves. The quartz tube 65 is forcibly evacuated with the vacuum pump. The source gases do not stagnate in anywhere and the flow rates thereof are smoothly automatically controlled. Accordingly, switching between compositions during the formation of the pair constituting the quantum well is quickly achieved.

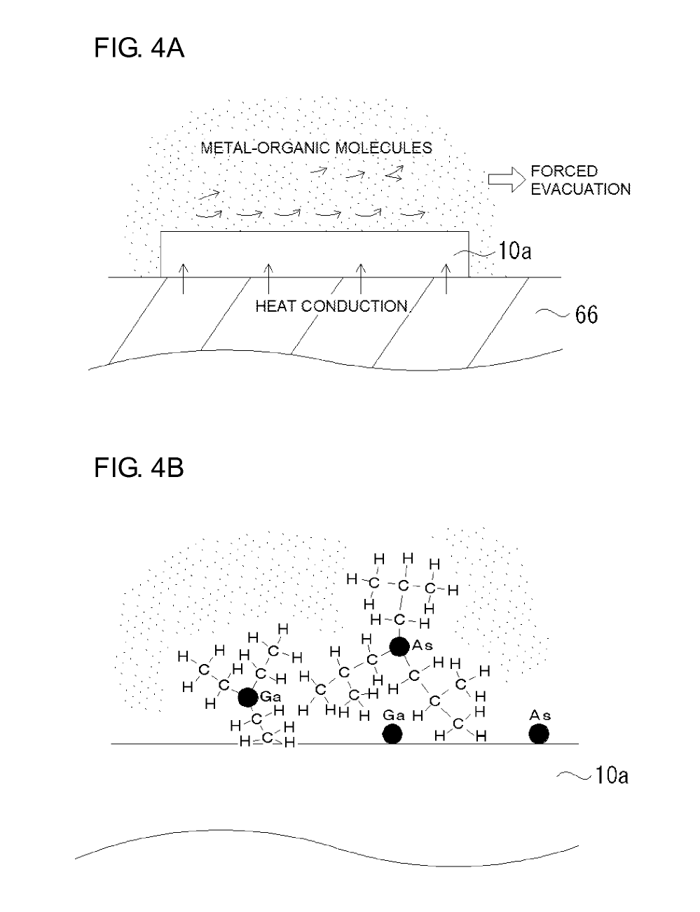

FIG. 4A illustrates flow of metal-organic molecules and thermal flow. FIG. 4B is a schematic view of metal-organic molecules on a substrate surface. The surface temperature of the epitaxial wafer 10a is monitored. The surface temperature is 450° C. or more and 500° C. or less. When metal-organic molecules having a large size illustrated in FIG. 4B flow over the wafer surface, metal-organic molecules that decompose to contribute to crystal growth are probably limited to molecules in contact with the surface and molecules present within a thickness range extending for a length of several metal-organic molecules from the surface.

However, when the epitaxial wafer surface temperature or the substrate temperature is excessively low of less than 450° C., large metal-organic molecules, in particular, carbon is not sufficiently decomposed or removed and is incorporated into the epitaxial wafer 10a. The carbon incorporated into III-V compound semiconductors serves as a p-type impurity and unintended semiconductor elements are formed. Thus, the intrinsic functions of the semiconductors are degraded, resulting in degradation of the performance of the produced semiconductor elements.

When source gases are selected with electromagnetic valves so as to correspond to the chemical compositions of the pair and introduced under forced evacuation with a vacuum pump, after slight growth of a crystal having an old chemical composition due to inertia, a crystal having a new chemical composition can be grown without being influenced by the old metal-organic source gases. As a result, a sharp composition change can be achieved at the heterointerface. This means that the old metal-organic source gases do not substantially remain in the quartz tube 65.

When the type-II MQW 3 is formed through growth in a temperature range more than 500° C., the projections or depressions are not formed and the GaAsSb layers of the MQW considerably undergo phase separation. For this reason, such growth should be avoided. However, on the other hand, as described above, when a growth temperature of less than 450° C. is employed, carbon necessarily contained in source gases is incorporated into the epitaxial wafer. The incorporated carbon functions as a p-type impurity and hence causes degradation of the performance.

It is another point that growth of the epitaxial layer structure in FIG. 1 by all metal-organic source MOVPE is continued within the same growth chamber or the same quartz tube 65 from growth of the substrate-side n-type InP cladding layer 2, through formation of the MQW 3, to formation of the surface-side p-type InP cladding layer 4 and the p-type InGaAs contact layer 5. A main reason that the growth by all metal-organic source MOVPE can be continued within the same growth chamber is that phosphorus- (P-) containing layers can be continuously grown without problems after growth of other layers. In III-V compound semiconductors, a large number of P-containing layers are used, such as an InP cladding layer and an InGaAsP cladding layer.

When phosphorus-containing layers such as an InP cladding layer are grown by, for example, MBE (molecular beam epitaxy), as described above, the following problem is caused.

In MBE, the sources used are solid sources. Accordingly, the source of phosphorus (P) for an InP window layer is solid phosphorus. Thus, as the deposition proceeds, solid phosphorus that is a residue from the deposition accumulates on the walls of the deposition chamber. The solid phosphorus source has high ignitability. Hence, there is a high probability of the occurrence of fire accidents when the apparatus is in an open state, such as during charging sources or during maintenance in MBE. A preventive measure against fire accidents needs to be taken.

The above-described problem can be avoided in all metal-organic source MOVPE. Advantages of growing phosphorus-containing layers such as InP by all metal-organic source MOVPE are as follows.

(E1) All metal-organic source MOVPE (also standard MOVPE) does not use any solid material as the P source and hence is excellent in terms of safety and the like. In addition, MOVPE is advantageous in terms of growth efficiency, compared with MBE.
(E2) All metal-organic source MOVPE uses, as source gases for InP, only metal-organic sources such as TBP (tertiarybutylphosphine) and TMI (trimethylindium). Thus, thermal decomposition is easily achieved and the growth temperature can be set to 500° C. or less. An inorganic substance PH₃ (phosphine) serving as a phosphorus source is not decomposed at a low temperature of 500° C. or less and cannot contribute to the growth. When the growth temperature is set to a high temperature of more than 500° C., thermal decomposition of the type-II MQW tends to be caused and it becomes difficult to form a normal MQW. When an InP layer or the like is deposited by all metal-organic source MOVPE, a multi-quantum well layer (active layer) having high crystallinity is maintained and, for example, the surface-side InP cladding layer 4 can be formed. When the surface-side InP cladding layer 4 is formed by all metal-organic source MOVPE, since only metal-organic sources are used as the source gases as described above, the source gases are thermally decomposed at 500° C. or less and the surface-side InP cladding layer 4 can be grown at this thermal decomposition temperature. Regarding such low-temperature growth of the surface-side InP cladding layer 4, all metal-organic source MOVPE is superior to other methods.
(E3) Since the epitaxial layers are continuously grown in the same single growth chamber, the epitaxial wafer (light-emitting element) 10 in FIG. 1 does not have any regrown interface. Regrown interfaces satisfy at least one of an oxygen concentration of 1×10¹⁷ cm⁻³ or more and a carbon concentration of 1×10¹⁷ cm⁻³ or more. Accordingly, such a regrown interface has low crystallinity and the epitaxial layer structure tends not to have a smooth surface. In the present invention, the oxygen and carbon concentrations are each less than 1×10¹⁷ cm⁻³ except for the epi-substrate interface between the III-V compound semiconductor substrate and the substrate-side InP cladding layer 2.
(E4) Since the process is continuously performed in the same single growth chamber, the epitaxial wafer can be efficiently obtained in a short time.

All metal-organic source MOVPE is used to perform growth from the type-II (InGaAs/GaAsSb) MQW 3 to the InGaAs contact layer 5 at a growth temperature of 500° C. or less and 450° C. or more. As a result, (F1) high crystallinity can be ensured in the type-II MQW in which the number of pairs is 25 or more, or 50 or more; and (F2) projections or depressions can be formed at a number density of 100 cm⁻² or more in the surface of the contact layer 5.

### EXAMPLES

The epitaxial wafer (light-emitting element) 10 in FIG. 1 was varied in terms of the number of pairs of the MQW and the growth temperature and was measured in terms of various properties: (InP substrate/substrate-side n-type InP cladding layer (thickness: 1000 nm, Si concentration: 1×10¹⁸ cm⁻³)/type-II (InGaAs (4 nm) and GaAsSb (4 nm)) MQW/surface-side p-type InP cladding layer (thickness: 800 nm, Zn concentration: 1×10¹⁸ cm⁻³)/p-type InGaAs contact layer (thickness: 200 nm, Zn concentration: 1×10¹⁹ cm⁻³)).

### Example 1

### Influence of Number of Pairs of MQW

The following five samples were used. The growth conditions and the like are described in Table I.

(Comparative example B1): 15 pairs, growth temperature of 500° C.
(Invention example A1): 50 pairs, growth temperature of 500° C.
(Invention example A2): 150 pairs, growth temperature of 500° C.
(Invention example A3): 250 pairs, growth temperature of 500° C.
(Invention example A4): 350 pairs, growth temperature of 500° C.

Measurement items: 1. Density of projections or depressions having diameter of 30 μm or less, and 2. Intensity, peak wavelength, and full width at half maximum of photoluminescence at room temperature.

### 1. Projections or Depressions in Surface of Contact Layer

Projections or depressions in the surface of the contact layer will be first described. FIGS. 5A, 5B, and 5C are schematic views respectively illustrating the surfaces of the contact layers in the cases of 50 pairs (Invention example A1), 150 pairs (Invention example A2), and 250 pairs (Invention example A3). In the case of 50 pairs in FIG. 5A, the density is so low that, with effort, a projection or depression can be captured within the field of view. This number density is 100 cm². As the number of pairs is increased from 150 to 250, the number density is increased from 5×10⁴ cm⁻² to 1×10⁶ cm⁻².

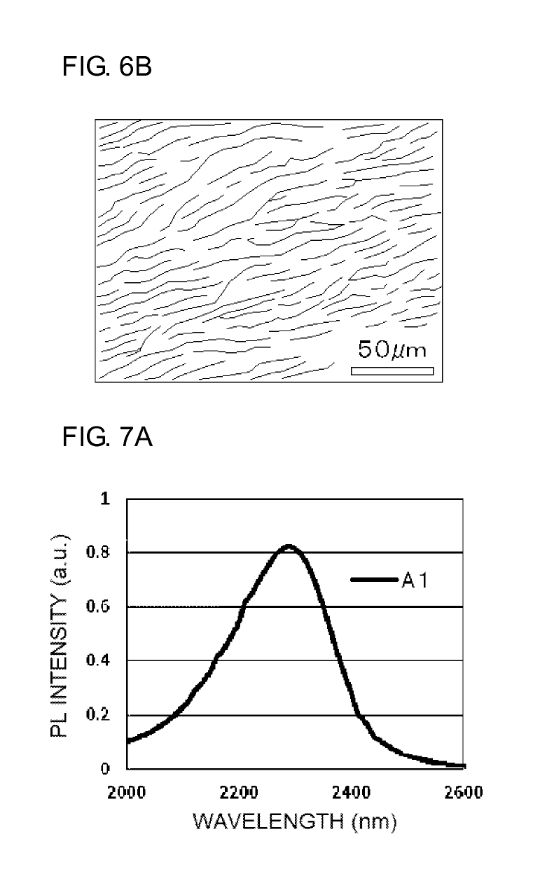

FIGS. 6A and 6B are schematic views respectively illustrating the surfaces of the contact layers in the cases of 15 pairs (Comparative example B1) and 350 pairs (Invention example A4). In the case of 15 pairs, the number density is 30 cm². In FIG. 6A, a single projection or depression is illustrated in the field of view. However, when the field of view is randomly selected, mostly, nothing is captured therein. In contrast, in FIG. 6B, projections or depressions have a number density of more than 10⁶ cm⁻² and merge into a flow-like form. The density of projections or depressions having such a form cannot be determined.

### 2. Photoluminescence at Room Temperature

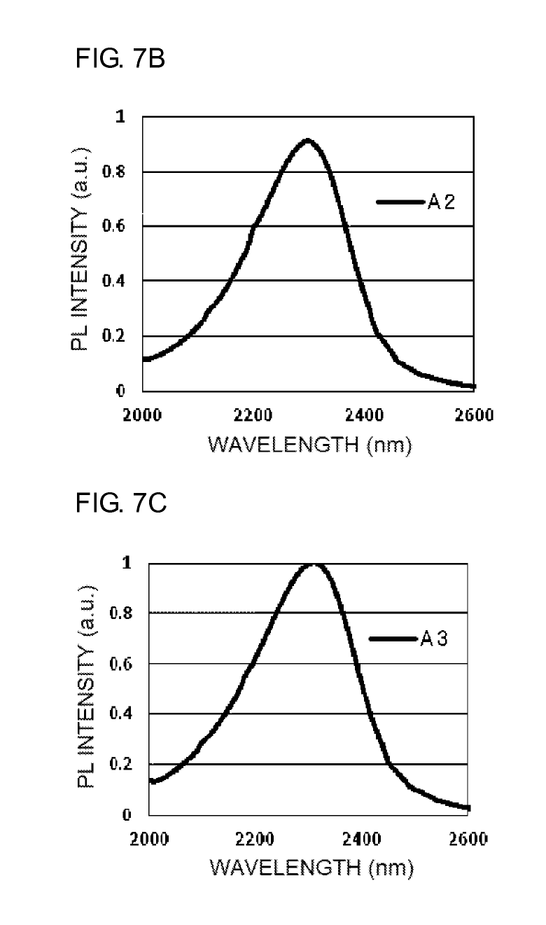

FIGS. 7A to 7C are graphs in which photoluminescence (PL) intensity is plotted against wavelength in Invention examples A1 to A3. The wavelength region extends from 2000 nm to 2600 nm. The peak wavelengths in Invention examples A1 to A3 uniformly fall within 2300 nm±10 nm. The peak intensities are high relative intensities of 0.8 and 0.9 with respect to the intensity of Invention example A3 defined as 1.

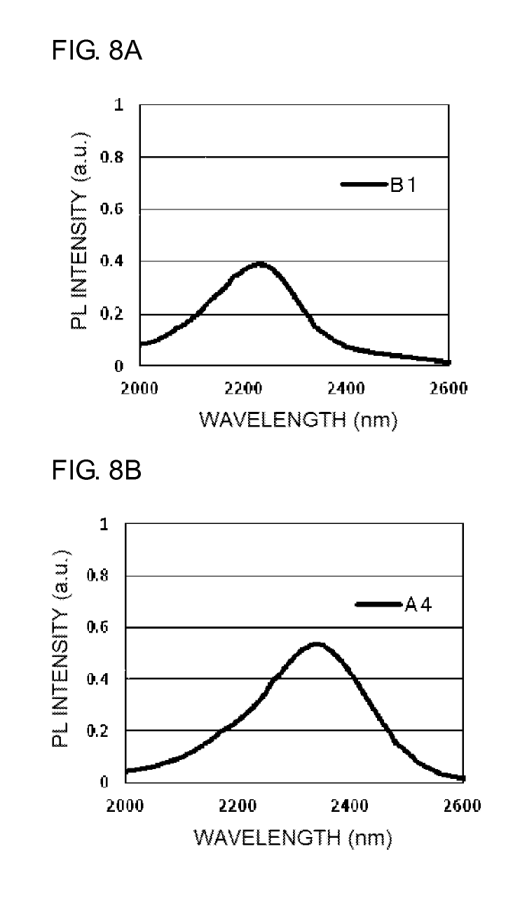

FIGS. 8A and 8B are graphs in which photoluminescence (PL) intensity is plotted against wavelength respectively in the case of 15 pairs (Comparative example B1) and 350 pairs (Invention example A4). The peak wavelength in Comparative example B1 is 2230 nm, which is shorter than that of Invention examples A1 to A3 by about 70 nm. In contrast, Invention example A4 has a peak wavelength of 2340 nm, which is longer by about 40 nm. Comparative example B1 has a peak intensity of 0.4 and Invention example A4 has a peak intensity of 0.5. Comparative example B1 in which the number of pairs is 15 is out of the scope of the present invention and has an inferior emission characteristic, compared with other examples. Invention example A4 in which the number of pairs is 350, which is 25 or more but excessively large, also has an inferior emission characteristic, compared with the other Invention examples.

These results are summarized in Table I.

TABLE 1

| | | Comparative | Invention | Invention | Invention | Invention |
|---|---|---|---|---|---|---|
| | | example B1 | example A1 | example A2 | example A3 | example A4 |
| Structure of | Number of pairs | 15 | 50 | 150 | 250 | 350 |
| MQW | | | | | | |
| Growth | Growth | 500 | 500 | 500 | 500 | 500 |
| condition | temperature (° C.) | | | | | |
| Measurement | Number density | 30 | 100 | 5 × 10⁴ | 1 × 10⁶ | — |
| results | of projections or | | | | | |
| | depressions | | | | | |
| | having diameter | | | | | |
| | of 30 μm or less | | | | | |
| | on epitaxial | | | | | |
| | wafer (/cm²) | | | | | |
| | PL intensity in | 0.4 | 0.8 | 0.9 | 1 | 0.5 |
| | epitaxial wafer at | | | | | |
| | room temperature | | | | | |
| | (relative | | | | | |
| | intensity) | | | | | |
| | PL peak | 2230 | 2290 | 2300 | 2310 | 2340 |
| | wavelength in | | | | | |
| | epitaxial wafer at | | | | | |
| | room temperature | | | | | |
| | (nm) | | | | | |
| | Full width at half | 53 | 48 | 48 | 52 | 50 |
| | maximum of PL | | | | | |
| | peak in epitaxial | | | | | |
| | wafer at room | | | | | |
| | temperature | | | | | |
| | (meV) | | | | | |

The above-described results indicate the following: epitaxial wafers (light-emitting elements) of Invention examples each having 25 or more pairs have a predetermined emission intensity; and, of these, epitaxial wafers (light-emitting elements) each having 50 to 250 pairs particularly have a sufficiently high emission intensity.

### Example 2

### Influence of Growth Temperature

Subsequently, the growth temperature for the type-II MQW was varied in the range of 450° C. to 525° C. and the same characteristics as in Example 1 were measured. The following samples were used. Invention example A3 is the same as that in Example 1.

(Invention example A5): 250 pairs, growth temperature of 450° C.
(Invention example A3): 250 pairs, growth temperature of 500° C.
(Invention example A6): 250 pairs, growth temperature of 525° C.

### 1. Projections or Depressions in Surface of Contact Layer

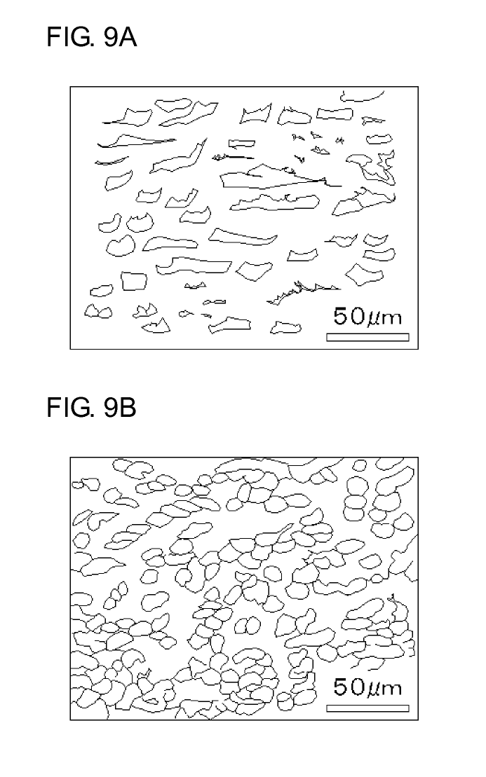

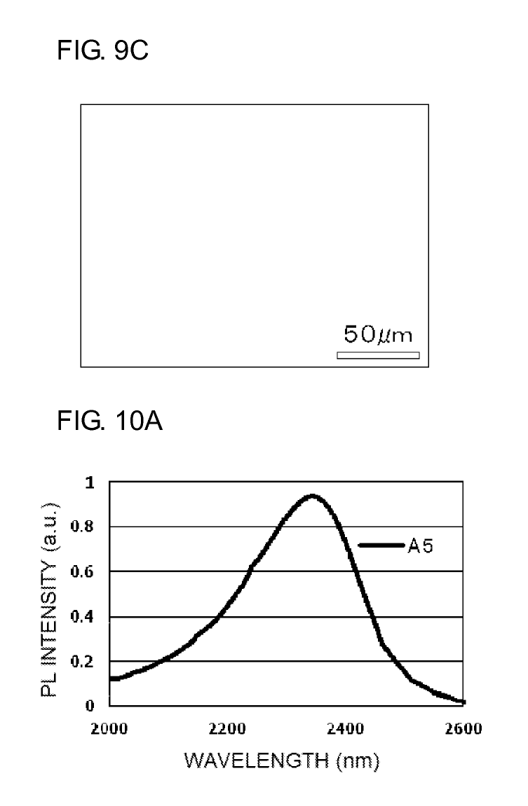

FIGS. 9A, 9B, and 9C are schematic views respectively illustrating the surfaces of the contact layers in the cases of a growth temperature of 450° C. (Invention example A5), a growth temperature of 500° C. (Invention example A3), and a growth temperature of 525° C. (Invention example A6). In the case of 450° C. in FIG. 9A, elongated strip-shaped projections or depressions are generated. In this case, regarding the feature of having a diameter of 30 μm or less, the diameter is measured in the shorter length direction.

In this case, the number density is 3×10⁵ cm⁻². When the growth temperature is set to 500° C., the number density slightly increases to 1×10⁶ cm⁻². However, at the growth temperature of 525° C., no generation is observed, that is, zero, in the surface of the contact layer.

### 2. Photoluminescence at Room Temperature

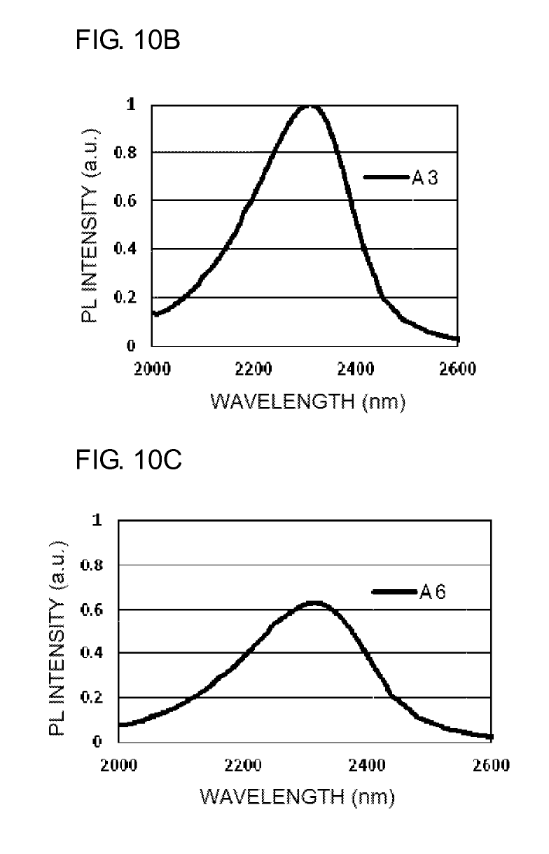

FIGS. 10A to 10C are graphs in which photoluminescence (PL) intensity is plotted against wavelength in Invention examples A5, A3, and A6. The peak wavelength in Invention example A5 is 2340 nm. The peak intensity is a high relative intensity of 0.9 with respect to the intensity of Invention example A3 defined as 1. Invention example A6 has a low peak intensity of 0.6, which may be resulted from no generation of projections or depressions due to the high growth temperature. In addition, the full width at half maximum is a large value of 54 meV, which indicates degradation of crystallinity of the MQW.

The results are summarized in Table II.

TABLE II

| | | Invention | Invention | Invention |
|---|---|---|---|---|
| | | example | example | example |
| | | A5 | A3 | A6 |
| Structure of | Number of pairs | 250 | 250 | 250 |
| MQW | | | | |
| Growth | Growth | 450 | 500 | 525 |
| condition | temperature (° C.) | | | |
| Measurement | Number density | 3 × 10⁵ | 1 × 10⁶ | 0 |
| results | of projections or | | | |
| | depressions | | | |
| | having diameter | | | |
| | of 30 μm or less | | | |
| | on epitaxial | | | |
| | wafer (/cm²) | | | |
| | PL intensity in | 0.9 | 1 | 0.6 |
| | epitaxial wafer at | | | |
| | room temperature | | | |
| | (relative | | | |
| | intensity) | | | |
| | PL peak | 2340 | 2310 | 2320 |
| | wavelength in | | | |
| | epitaxial wafer at | | | |
| | room temperature | | | |
| | (nm) | | | |
| | Full width at half | 51 | 52 | 54 |
| | maximum of PL | | | |
| | peak in epitaxial | | | |
| | wafer at room | | | |
| | temperature | | | |
| | (meV) | | | |

The above-described results indicate the following: unless the growth temperature is in the range of 450° C. or more and 500° C. or less, even a sample of Invention example having a large number of pairs, 250, does not have a sufficiently high emission intensity.

Embodiments according to the present invention have been described. However, the above-disclosed embodiments according to the present invention are mere examples and the scope of the present invention is not limited to these embodiments of the invention. The scope of the present invention is indicated by Claims and also embraces all the modifications within the meaning and range of equivalency of the Claims.

### INDUSTRIAL APPLICABILITY

An epitaxial wafer according to the present invention is produced so as to have a type-II MQW formed of III-V compound semiconductors and having a large number of pairs by appropriately setting the growth method and the growth temperature. From the epitaxial wafer, a light-emitting element can be obtained that is configured to emit light with a sufficiently high intensity in the near infrared region.

1. A method for producing an epitaxial wafer including an epitaxial layer structure formed of III-V compound semiconductors, the method comprising:
a step of growing an active layer having a type-II multi-quantum well structure on a III-V compound semiconductor substrate,
wherein, the type-II multi-quantum well structure is formed by metal-organic vapor phase epitaxy using only metal-organic sources such that a number of pairs of the type-II multi-quantum well structure is 25 or more.

2. The method for producing an epitaxial wafer according to claim 1, wherein the type-II multi-quantum well structure is grown at a growth temperature of 500° C. or less to form projections or depressions at a number density of 100/cm² or more in a surface of the epitaxial layer structure.

3. The method for producing an epitaxial wafer according to claim 1, wherein the type-II multi-quantum well structure is grown at a growth temperature of 450° C. or more.

4. The method for producing an epitaxial wafer according to claim 1, further comprising a step of forming a contact layer formed of a III-V compound semiconductor, the step being performed after the step of forming the type-II multi-quantum well structure, wherein the metal-organic vapor phase epitaxy using only metal-organic sources is performed within the same growth chamber from initiation of growth of the multi-quantum well structure to end of growth of the contact layer, so that a step of forming a regrown interface does not occur between the step of forming the multi-quantum well structure and the step of forming the contact layer.

5. The method for producing an epitaxial wafer according to claim 1, wherein the epitaxial layer structure includes a phosphorus-containing layer.

6. The method for producing an epitaxial wafer according to claim 1, wherein the III-V compound semiconductor substrate is an InP substrate and the type-II multi-quantum well structure has pairs of (InGaAs/GaAsSb).

7. An epitaxial wafer for a light-emitting element, the epitaxial wafer including an epitaxial layer structure formed of III-V compound semiconductors, the epitaxial wafer comprising:
a III-V compound semiconductor substrate, and
a type-II multi-quantum well structure disposed on the substrate,
wherein a number of pairs of the type-II multi-quantum well structure is 25 or more.

8. The epitaxial wafer according to claim 7, wherein a surface of the epitaxial layer structure has projections or depressions at a number density of 100/cm² or more.

9. The epitaxial wafer according to claim 7, further comprising a III-V compound semiconductor contact layer in a surface of the epitaxial layer structure.

10. The epitaxial wafer according to claim 9, wherein the contact layer is formed of InGaAs.

11. The epitaxial wafer according to claim 7, wherein the type-II multi-quantum well structure is a multi-quantum well structure having pairs of (InGaAs/GaAsSb).

12. The epitaxial wafer according to claim 7, comprising a substrate-side first-conductivity-type InP cladding layer disposed on a substrate side and a surface-side second-conductivity-type InP cladding layer disposed on a surface side such that the cladding layers sandwich the type-II multi-quantum well structure therebetween.

13. The epitaxial wafer according to claim 7, wherein no regrown interface is present between the type-II multi-quantum well structure and a surface of the epitaxial layer structure.

14. A light-emitting element produced from the epitaxial wafer according to claim 7.
